(19) United States
(12) Patent Application Publication
(10) Pub. No.: US 2015/0035416 A1
(43) Pub. Date: Feb. 5, 2015

(54) Housing Locking Tabs

(71) Applicant: Kevin Yang, Lomita, CA (US)

(72) Inventor: Kevin Yang, Lomita, CA (US)

(21) Appl. No.: 13/957,194

(22) Filed: Aug. 1, 2013

(51) Int. Cl. H05K 5/02

(52) U.S. Cl. CPC H05K 5/0221; H05K 5/0247
USPC 312/223.1

(57) ABSTRACT

A ballast locking tab system has a first shell having a first shell horizontal portion and a first shell vertical portion connecting to the first shell horizontal portion. The first shell is made of a first sheet of metal. A main tab is formed on the first shell. The main tab is formed between a pair of guiding slots, and the main tab is pointing away from the first shell horizontal portion. A second shell has a second shell horizontal portion connecting to a second shell vertical portion. The second shell is made of a second sheet of metal. A slot panel is formed on the second shell. The slot panel is displaced from the second shell vertical portion to form a slot panel opening sized to receive the main tab.

### DISCUSSION OF RELATED ART

Electronic ballast is required for driving and providing a regulated power supply for fluorescent lighting or light emitting diode based lighting. Typically, electronic ballast is housed in a metal box. The electronic ballast has a circuit connected to lead wires. A variety of electronic components are mounted on the circuit. Electronic ballast housing has typically required riveting, and metal bending for securely closing the electronic ballast housing. LED drivers also have housing for the electronic components of the drivers.

### SUMMARY OF THE INVENTION

A ballast locking tab system has a first shell having a first shell horizontal portion and a first shell vertical portion connecting to the first shell horizontal portion. The first shell is made of a first sheet of metal. A main tab is formed on the first shell. The main tab is formed between a pair of guiding slots, and the main tab is pointing away from the first shell horizontal portion. A second shell has a second shell horizontal portion connecting to a second shell vertical portion. The second shell is made of a second sheet of metal. A slot panel is formed on the second shell. The slot panel is displaced from the second shell vertical portion to form a slot panel opening sized to receive the main tab.

A locking tab is formed on the main tab, and the locking tab is formed at a locking tab cutout. The locking tab is bent out of parallel from a plane of the first shell vertical portion. The locking tab is configured to lock to a slot panel engaging edge. The locking tab is pointing toward the first shell horizontal portion.

The pair of guiding slots each have a first guiding slot portion and a second guiding slot portion. The second guiding slot portion is tapered to have a wider opening than the first guiding slot portion. The lower shell port is configured to receive passage of electrical wiring through the lower shell port. The lower shell tongue protrusions extend inward. The locking tab is disposed outward such that the locking tab bends outward away from a plane of the first shell vertical portion, wherein the slot panel is disposed inward such that the slot panel protrudes inward from a plane of the second shell vertical portion. The locking tab is biased and bent to engage against an abutment edge of the lower shell formed at the slot panel. The first shell is an upper shell having an upper shell horizontal portion and an upper shell vertical portion connecting to the upper shell horizontal portion. The second shell is a lower shell having a lower shell horizontal portion connecting to a lower shell vertical portion.

### BRIEF DESCRIPTION OF THE DRAWINGS

FIG. 1 is a perspective exploded view of the present invention.

FIG. 2 is a cross section of the present invention.

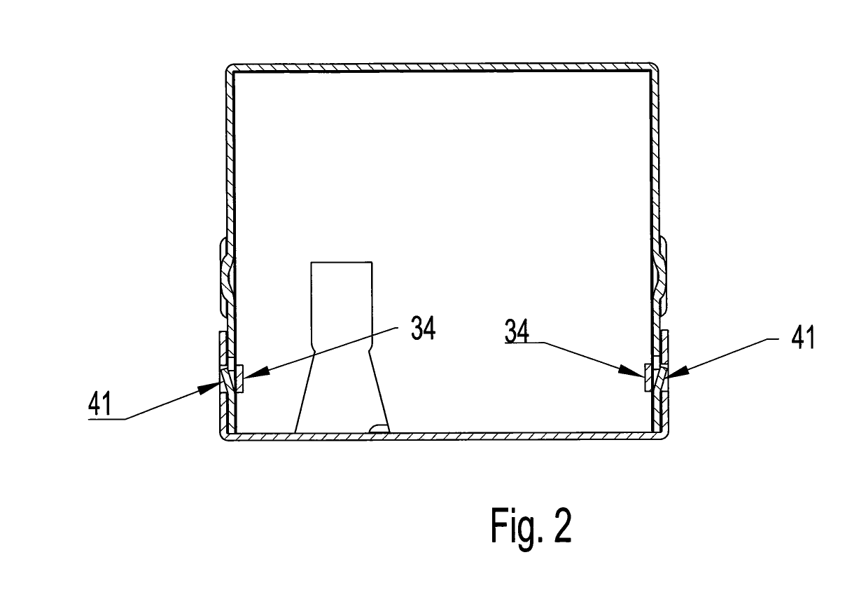

FIG. 3 is a perspective with cross-section cutaway of the present invention.

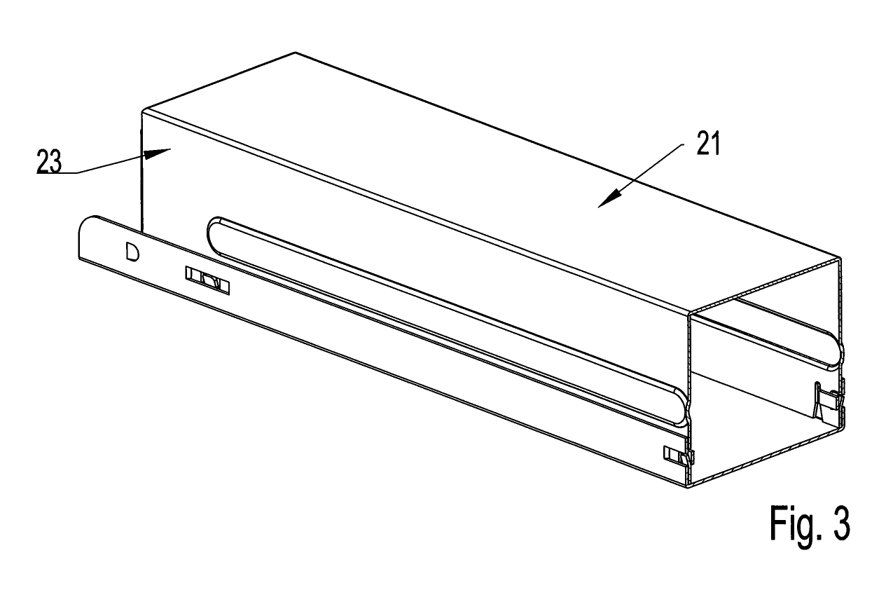

FIG. 4 is a close-up view of FIG. 3.

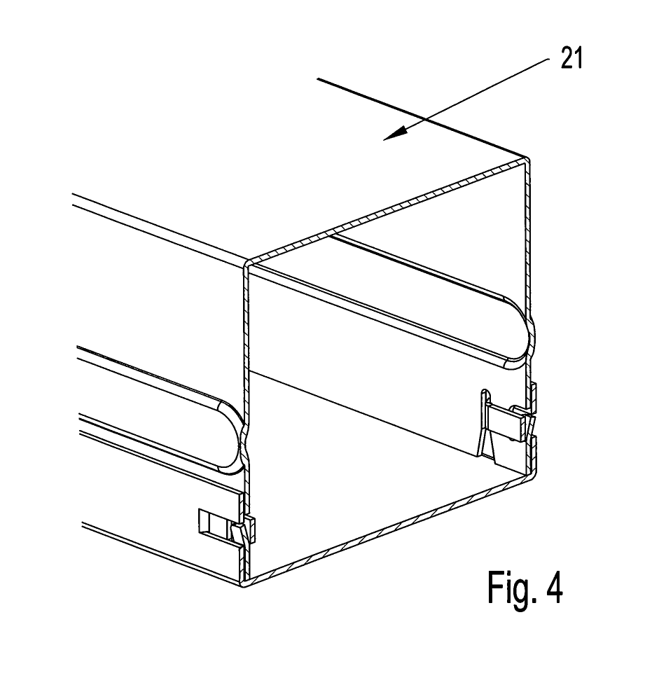

FIG. 5 is an unassembled view of the engaging side of the locking tab mechanism.

FIG. 6 is an assembled view of the engaging side of the locking tab mechanism.

FIG. 7 is an unassembled view of the not engaging side of the locking tab mechanism.

FIG. 8 is an assembled view of the engaging side of the locking mechanism.

The following flat list of elements can be a useful guide in referencing the elements of the drawings.

20 Upper Shell

21 Upper Shell Horizontal Portion

22 Upper Shell Front Vertical Wall

23 Upper Shell Side Vertical Wall

24 Main Tab

25 First Guiding Slot Portion

26 Locking Tab Cutout

27 Locking Tab

28 Second Guiding Slot Portion

29 Main Tab Supports

30 Lower Shell

31 Lower Shell Horizontal Portion

32 Lower Shell Port

33 Slot Panel Lower Edge

34 Slot Panel

35 Slot Panel Upper Edge

36 Lower Shell Tongue Protrusions

37 Lower Shell Vertical Portion

41 Locking Tab Abutment

### DETAILED DESCRIPTION OF THE PREFERRED EMBODIMENT

An electronic component housing can be formed as a ballast housing that is generally rectangular in shape and made of a sheet metal that is punched and bent. One or two sheets of sheet can be used for fabricating a ballast housing. The ballast housing is mounted to a lighting fixture for providing a stable power source to the light apparatus.

As seen in the first figure, a ballast housing has an upper shell 20 that is connected to a lower shell 30. The upper shell has an upper shell horizontal portion 21 that is generally flat and forms the top part or bottom part of the box, depending upon the orientation of the housing. The upper shell horizontal portion 21 is preferably made of a sheet of metal that is folded downward at various locations to form a 90° angle between the upper shell horizontal portion 21 and sections connected to the upper shell horizontal portion 21. One of the sections connected to the upper shell vertical portion 21 is the upper shell front vertical wall 22. The upper shell front vertical wall 22 may have a variety of different connections to the upper shell side vertical wall 22. The upper shell side vertical wall is also connected to upper shell horizontal portion 21. The upper shell is preferably made of a single sheet of sheet metal.

The main tab 24 is preferably punched from the single sheet of sheet metal before the main tab 24 is bent along with the upper shell side vertical wall. The main tab 24 has a first guiding slot portion 25 that is generally wider at its entrance. The first guiding slot portion 25 is preferably trapezoidal shaped and has a continuation to a second guiding slot portion 28 that is more narrow than the opening entrance area of the first guiding slot portion 25. The main tab 24 is bounded at a left and right side of the main tab by a pair of guiding slots, and the guiding slots both include a first guiding slot portion 25 and a second guiding slot portion 28.

The main tab 24 extends from a pair of main tab supports 29. The main tab supports 29 extend from the upper shell side vertical wall, or from the upper shell front vertical wall. The main tab supports 29 have a prong configuration with locking tab cutout 26 between the main tab supports 29. The locking tab cutout 29 is cut into the main tab 24 to form a locking tab 27 and bending either inward or outward from the main tab 24. The bending provides a biased locking tab abutment 41 occurring between the upper shell vertical wall and the lower shell. The locking tab abutment 41 preferably clicks into place and locks the upper shell 20 to the lower shell 30.

The lower shell 30 preferably includes a lower shell horizontal portion 31 and a lower shell port 32 formed on the lower shell horizontal ocean 31. The lower shell port 32 could include a grommet to allow lead wire to enter and exit the ballast housing formed by the lower shell 30 and the upper shell 20. The lower shell horizontal portion preferably connects to a pair of lower shell vertical portions 37. The lower shell horizontal portion and lower shell vertical portion can be made of a single sheet of metal that is bent to form the lower shell vertical portion from the lower shell horizontal portion. The lower shell port 32 can be made smooth by bending or punching. It is preferred that the lower shell port 32 has an edge that is deburred to be smooth. The slot panel lower edge 33 is an edge of the lower shell horizontal portion.

The lower shell vertical portion 37 is punched with two pairs of slot panels 34. The slot panels are sized to receive an edge of the main tab 24. The slot panel is bounded by the slot panel lower edge at a lower edge and the slot panel is bounded by the slot panel upper edge along an upper edge of the slot panel. The slot panel 34 can be punched inward to provide an engagement surface for the locking tab 27 to engage against. The engagement surface can be the slot panel upper edge of the lower shell vertical portion. Preferably, the slot panel upper edge of the lower shell vertical portion has a thickness that is in abutment against the hook portion of the locking tab.

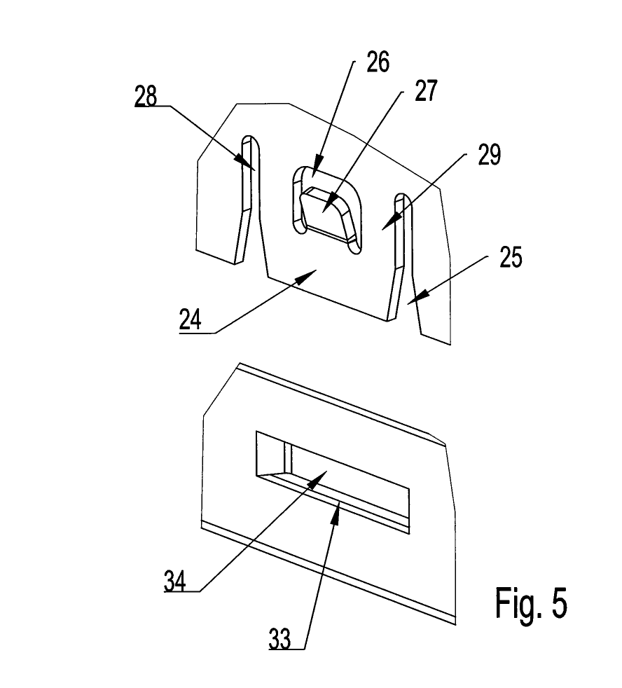

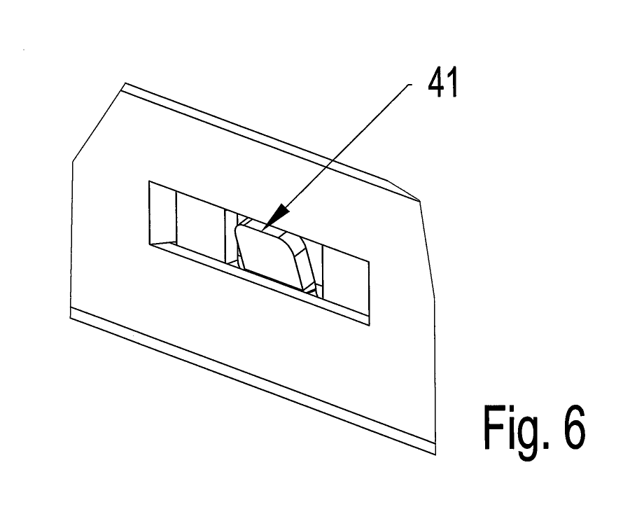

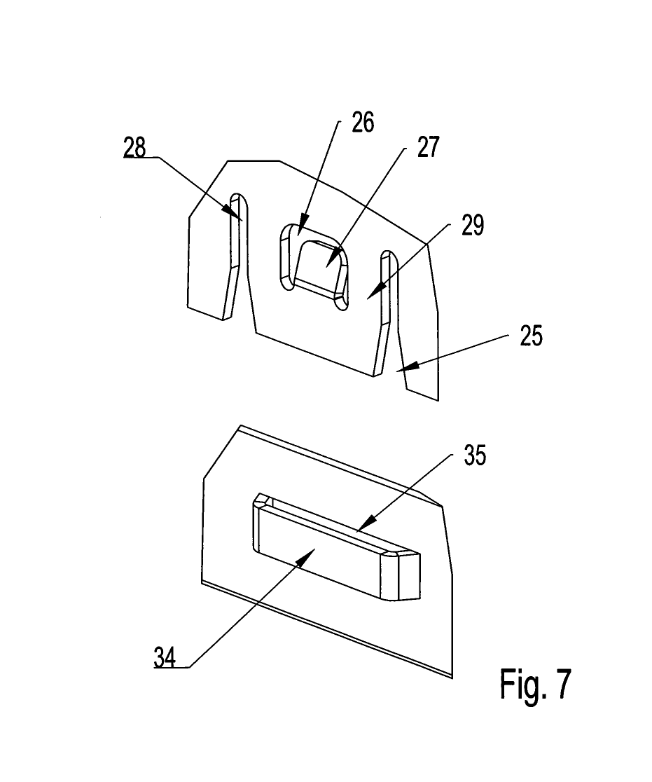

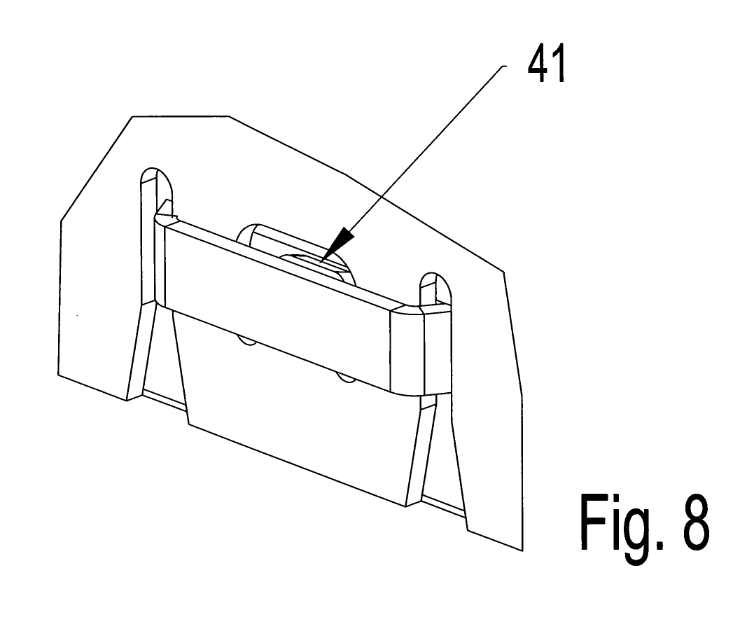

When the locking tab 27 is disposed outward, a user can use a screwdriver to bias the locking to unlock the locking tab from the slot panel upper edge. However, when the locking tab 27 is disposed inward, the user cannot use a tool to open the housing by disengaging the locking tab 27 from its locked position. The locking tab automatically locks when the lower shell vertical portion is pressed to the upper shell vertical portion. The engaging side of the locking mechanism is the side that the locking tab 27 makes engagement. The engaging side is the side that the locking tab is bent toward. The engaging side can be formed on the inside of the housing which would prevent manual disengagement with a screwdriver, or the engaging side can be formed on the outside of the housing which would allow manual disengagement with a screwdriver. The geometry of FIG. 5-8 can be inverted to allow the engaging side to be on the inside or the outside. It is preferred that the engaging side is on the inside so that inadvertent manual disengagement is less possible. Even if the engaging side is on the outside, the dimensions of the tabs can be made to sloppy tolerance such that interference fit provides greater retaining force. Optionally, some of the locking tabs can be made with the engaging side on the inside and then on the same housing, some of the locking tabs can be made with the engaging side on the outside.

The lower shell horizontal portion is also punched with lower shell tongue protrusions 36 that bend inward from an external surface of the lower shell vertical portion. The lower shell tongue protrusions can align a corner of the upper shell 20 to the lower shell 30.

The tab 24 generally has a tapered shape for connecting to the slot panel 34 of the lower shell. The slot panel 34 is preferably punched to provide an opening for receiving the tab 24. The slot panel opening preferably has a thickness accommodating the thickness of the tab 24. The tab 24 generally points downward and the locking tab 27 generally points upward. The slot panel 34 has an upper opening and a lower opening. The slot panel is formed as a panel that is preferably an elongated rectangular member. The elongated rectangular member is the panel portion of the slot panel.

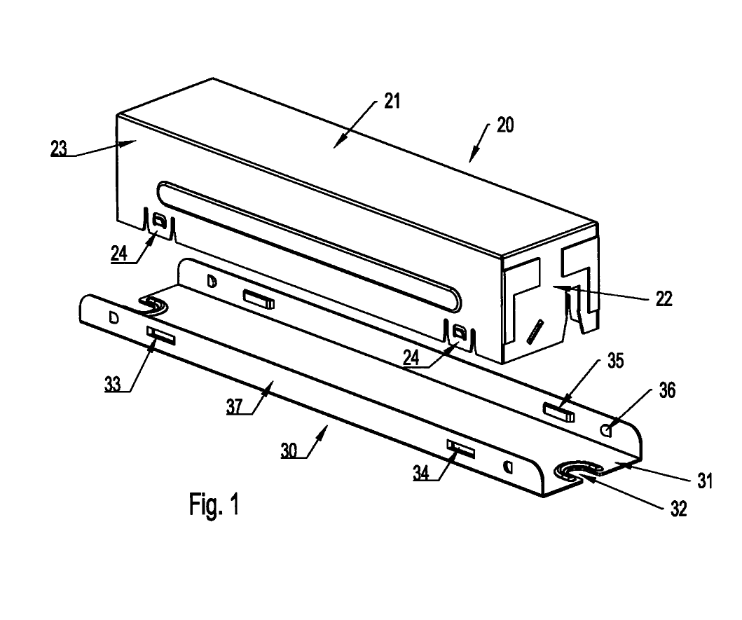

Rotating FIG. 1 by 180° makes the lower shell the upper shell and the upper shell the lower shell. After inversion, the slot panel 34 is now located on the upper shell, and the main tab is located on the lower shell. Because the strength of the connection is the same whether or not the slot panel is on the upper shell or lower shell, the upper shell or lower shell could be replaced by the terms ‘the first shell’ and ‘the second shell’.

1. A ballast locking tab system comprising:
a. a first shell having a first shell horizontal portion and a first shell vertical portion connecting to the first shell horizontal portion, wherein the first shell is made of a first sheet of metal;
b. a main tab formed on the first shell, wherein the main tab is formed between a pair of guiding slots, wherein the main tab is pointing away from the first shell horizontal portion;
c. a second shell having a second shell horizontal portion connecting to a second shell vertical portion, wherein the second shell is made of a second sheet of metal;
d. a slot panel formed on the second shell, wherein the slot panel is displaced from the second shell vertical portion to form a slot panel opening sized to receive the main tab; and further comprising
e. a locking tab formed on the main tab, wherein the locking tab is formed at a locking tab cutout, wherein the locking tab is bent out of parallel from a plane of the first shell vertical portion, wherein the locking tab is configured to lock to a slot panel engaging edge, wherein the locking tab is pointing toward the first shell horizontal portion.

2. The ballast locking tab system of claim 1, wherein the pair of guiding slots each have a first guiding slot portion and a second guiding slot portion, wherein the second guiding slot portion is tapered to have a wider opening than the first guiding slot portion.

3. The ballast locking tab system of claim 1, further comprising a lower shell port, configured to receive passage of electrical wiring through the lower shell port.

4. The ballast locking tab system of claim 1, further comprising lower shell tongue protrusions extending inward.

5. The ballast locking tab system of claim 1, wherein the locking tab is disposed outward such that the locking tab bends outward away from a plane of the first shell vertical portion, wherein the slot panel is disposed inward such that the slot panel protrudes inward from a plane of the second shell vertical portion.

6. The ballast locking tab system of claim 1, wherein the locking tab is biased and bent to engage against an abutment edge of the lower shell formed at the slot panel.

7. The ballast locking tab system of claim 1, wherein the first shell is an upper shell having an upper shell horizontal portion and an upper shell vertical portion connecting to the upper shell horizontal portion; wherein the second shell is a lower shell having a lower shell horizontal portion connecting to a lower shell vertical portion.

8. The ballast locking tab system of claim 7, wherein the pair of guiding slots each have a first guiding slot portion and a second guiding slot portion, wherein the second guiding slot portion is tapered to have a wider opening than the first guiding slot portion.

9. The ballast locking tab system of claim 7, further comprising a lower shell port, configured to receive passage of electrical wiring through the lower shell port.

10. The ballast locking tab system of claim 7, further comprising lower shell tongue protrusions extending inward.

11. The ballast locking tab system of claim 7, wherein the locking tab is disposed outward such that the locking tab bends outward away from a plane of the first shell vertical portion, wherein the slot panel is disposed inward such that the slot panel protrudes inward from a plane of the second shell vertical portion.

12. The ballast locking tab system of claim 7, wherein the locking tab is biased and bent to engage against an abutment edge of the lower shell formed at the slot panel.

13. The ballast locking tab system of claim 12, wherein the pair of guiding slots each have a first guiding slot portion and a second guiding slot portion, wherein the second guiding slot portion is tapered to have a wider opening than the first guiding slot portion.

14. The ballast locking tab system of claim 12, further comprising a lower shell port, configured to receive passage of electrical wiring through the lower shell port.

15. The ballast locking tab system of claim 12, further comprising lower shell tongue protrusions extending inward.

16. The ballast locking tab system of claim 12, wherein the locking tab is disposed outward such that the locking tab bends outward away from a plane of the first shell vertical portion, wherein the slot panel is disposed inward such that the slot panel protrudes inward from a plane of the second shell vertical portion.

17. The ballast locking tab system of claim 16, wherein the pair of guiding slots each have a first guiding slot portion and a second guiding slot portion, wherein the second guiding slot portion is tapered to have a wider opening than the first guiding slot portion.

18. The ballast locking tab system of claim 16, further comprising a lower shell port, configured to receive passage of electrical wiring through the lower shell port.

19. The ballast locking tab system of claim 16, further comprising lower shell tongue protrusions extending inward.

20. The ballast locking tab system of claim 16, wherein the pair of guiding slots each have a first guiding slot portion and a second guiding slot portion, wherein the second guiding slot portion is tapered to have a wider opening than the first guiding slot portion; further comprising a lower shell port, configured to receive passage of electrical wiring through the lower shell port, wherein the lower shell has a cutout for passage of electrical wiring.
